(19) United States
(12) Patent Application Publication
(10) Pub. No.: US 2008/0026491 A1
(43) Pub. Date: Jan. 31, 2008

(54) METHOD OF WAFER SEGMENTING

(76) Inventor: Shun-Ta Wang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/550,426

(22) Filed: Oct. 18, 2006

(30) Foreign Application Priority Data
Jul. 27, 2006 (TW) 095127509

(51) Int. Cl. H01L 21/66

(52) U.S. Cl. 438/15; 438/68; 438/114; 438/464; 438/458

(57) ABSTRACT

A method of wafer segmenting is provided. Initially, a wafer having a plurality of devices on a top surface thereof is provided. A passivation layer is formed on the top surface of the wafer to cover the devices. A bottom surface of the first bonding layer is attached to a lower surface of the wafer. In addition, a carrier wafer is provided. A second bonding layer is attached to the first bonding layer to bond the wafer to the support wafer. A segment process is performed to form a plurality of dies. Each die is maintained at the same distance between each other as the distance between the dies before the segment process. The passivation layer is removed and the devices are exposed. A wafer-level testing is performed upon the devices. The second bonding layer and the carrier wafer are removed thereafter.

### BACKGROUND OF THE INVENTION

1. Field of the Invention

The present invention is related to a method of wafer segmenting capable of maintaining a distance between dies, and particularly, to a method of wafer segmenting that divides the wafer into a plurality of dies, and performs a wafer-level testing thereafter.

2. Description of the Prior Art

In the past, chips have been fabricated by several complicated steps, which include device manufacturing, device testing, wafer segmenting, packaging, and chip testing. These steps are applied to most electric products, circuits, or semiconductor devices. However, some devices fabricated by different processes, e.g. micro-electromechanical system devices, cannot be performed by theses steps. The structure of MEMS devices includes mobile structures, such as springs, shafts, and gear wheals; or stationary structures, such as pins, trenches, or holes. The functions of the MEMS devices are tested after the MEMS device wafer has been divided into a plurality of dies and after the MEMS devices have been exposed. Therefore, the traditional chip-production processes have to be modified to be applied to dies having MEMS devices thereon after the MEMS device wafer is divided.

FIG. 1 and FIG. 2 are schematic diagrams illustrating a conventional method of wafer segmenting to divide a MEMS device wafer into a plurality of dies having MEMS devices thereon. As shown in FIG. 1, a device wafer 10 having a plurality of MEMS devices 12 on a top surface thereof is provided. A photoresist layer 14 is formed to cover the MEMS devices 12 that may protect the MEMS devices 12 from particle damage or mechanical force resulted from subsequent processes. The device wafer 10 is bonded to a carrier wafer 16, and a wafer segment process is performed. The device wafer 10 is divided by a blade into a plurality of individual dies 18 along predetermined positions. As shown in FIG. 2, the dies 18 are released from the carrier wafer 16 and are transferred into a chamber 20 to remove the photoresist 14. This step also exposes the MEMS devices 12, and afterward a die testing process is performed. After the die testing process, the known good dies 18 are picked up manually for the following packaging process.

The conventional method requires frequent manual operation that requires a high labor cost and time cost. In addition, each die cannot maintain the same distance between each other as the distance between the dies before the wafer segment process. As a result, the automatic wafer-level testing process is unable to be performed on the dies manufactured by the conventional method. And consequently, die throughput is difficult to be increased.

### SUMMARY OF THE INVENTION

It is therefore a primary objective of the present invention to provide a method of wafer segmenting capable of maintaining a distance between dies. The method of the present invention includes performing a wafer-level testing after the wafer segment process that may achieve the goal of batch production.

According to the present invention, a method of wafer segmenting capable of maintaining a distance between dies is provided. A device wafer having a plurality of devices on a top surface thereof is provided. A passivation layer is formed on the top surface of the device wafer to cover the devices. Then, a bottom surface of the device wafer is attached to a first bonding layer. A carrier layer is provided and a second bonding layer is utilized to adhere the first bonding layer and the carrier wafer. A wafer segment process is performed to segment the passivation layer and the device wafer to form a plurality of dies. Each die is maintained at the same distance between each other by means of the second bonding layer as the distance between the dies before the wafer segment process. And afterward, the passivation layer is removed to expose the devices and a wafer-level testing is performed. The second bonding layer and the carrier wafer are then removed.

The dies, which are processed by the method of the present invention, are maintained at the same distance and on the same plane as that of the dies before the wafer segment process. The following processes including removing the passivation layer and performing the wafer-level testing are capable of increasing die throughput and capable of saving labor cost and time cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating conventional method of wafer segmenting to divides a MEMS device wafer into a plurality of dies having MEMS devices thereon.

FIGS. 3 to 8 are schematic diagrams illustrating a method of wafer segmenting capable of maintaining a distance between dies according to a preferred embodiment of the present invention.

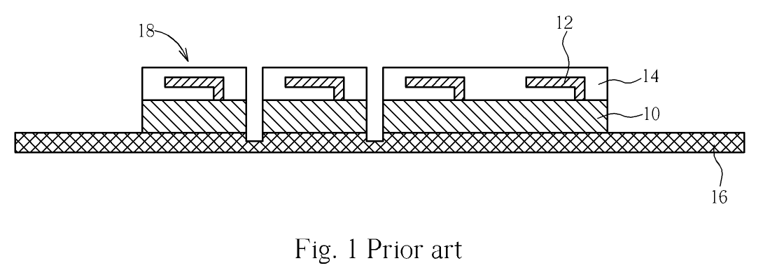

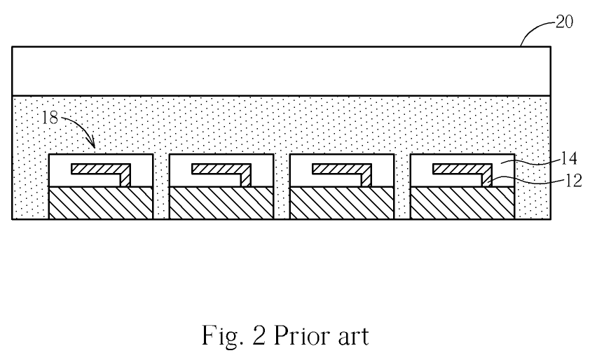

### DETAILED DESCRIPTION

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

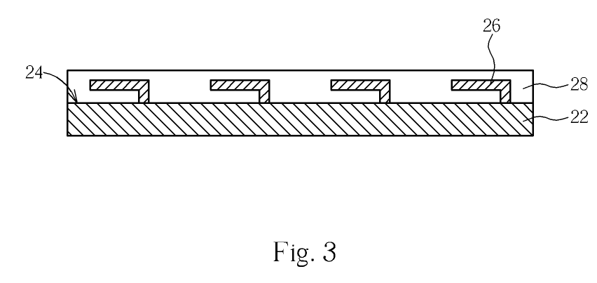

FIGS. 3 to 8 are schematic diagrams illustrating a method of wafer segmenting capable of maintaining a distance between dies according to a preferred embodiment of the present invention. As shown in FIG. 3, a device wafer 22 having a plurality of devices 26 on a top surface 24 thereof is provided. A passivation layer 28 is formed on the top surface 24 of the device wafer 22 to cover the devices 26. In this preferred embodiment, the devices 26 are MEMS devices of 3D structures, and other devices are allowable, such as electronic circuit devices, optical devices, or other kinds of semiconductor devices. The type of the device depends on the end product. The passivation layer 28 uses photoresist as material. The photoresist is solidified and is able to protect the devices 26 from particle damage and mechanical forces resulting from the following process. The passivation layer 28 may also use other suitable materials having the ability to protect the devices 26.

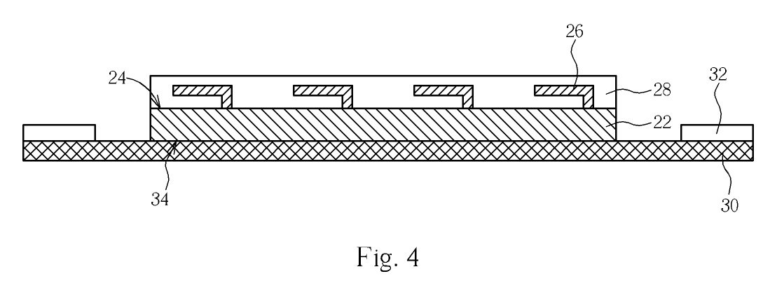

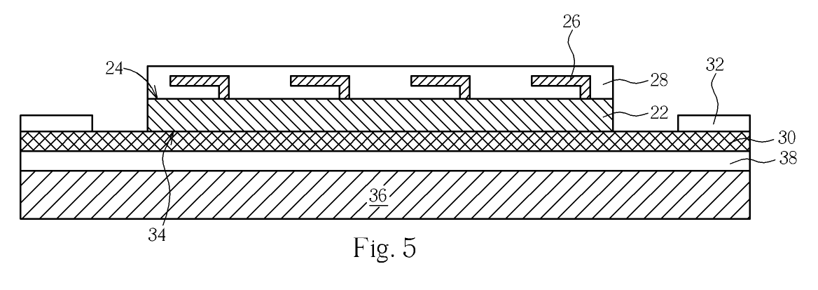

Please refer to FIG. 4, a first bonding layer 30 is provided. The edges of first bonding layer 30 are connected to a frame 32. A bottom surface 34 of the device wafer 22 is attached to the first bonding layer 30. In this preferred embodiment, the first bonding layer 30 is UV tape, and blue tape or other extendable film is allowable. As shown in FIG. 5, a carrier wafer 36 and a second bonding layer 38 are provided. The second bonding layer 38 is used to bond the first bonding layer 30 and the device wafer 22 on the carrier wafer 36. In this preferred embodiment, the second bonding layer 38 uses thermal tape as material and the carrier wafer 36 is a glass wafer. Other materials may be selected as the second bonding layer 38 or the carrier wafer 36 depending on requirements.

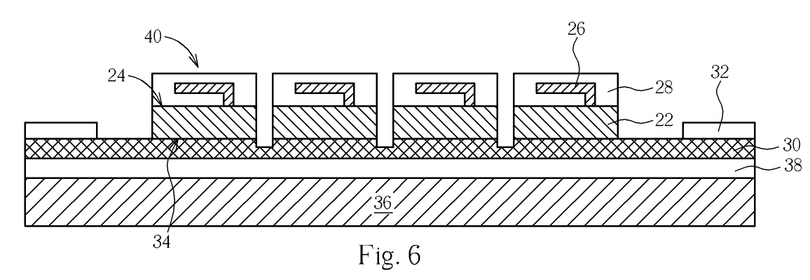

A wafer segment process is performed after the device wafer 22 is bonded to the carrier wafer 36. As shown in FIG. 6, the wafer segment process is performed along predetermined positions. The segment process may use a blade, laser, etching, or other segment method to segment the passivation layer 28 and the device wafer 22. The performance of the wafer segment process approaches the first bonding layer 30, but it does not penetrate the first bonding layer 30. Therefore, a plurality of dies 40 is formed. Each die 40 is maintained at the same distance between each other by means of the second bonding layer 38 as the distance between the dies 40 before the wafer segment process. The passivation layer 28 covers the device 26 of the device wafer 22 and protects the devices 26 from mechanical forces and particle damage resulting from the wafer segment process to keep the structure of the devices 26 clean. Since the passivation layer 28 is photoresist in this preferred embodiment, the passivation layer 28 may be removed by a strip solution or a plasma etching process. Therefore, the devices 26 are exposed for the following testing. Other methods for removing the passivation layer 28 can be used, depending on the material of the passivation layer 28; in addition, the method will not damage the device 26 while removing the passivation layer 28.

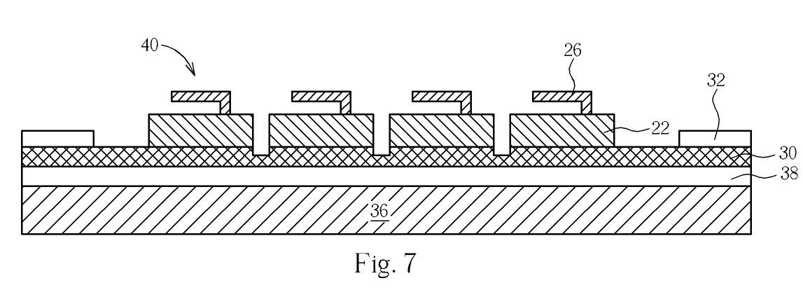

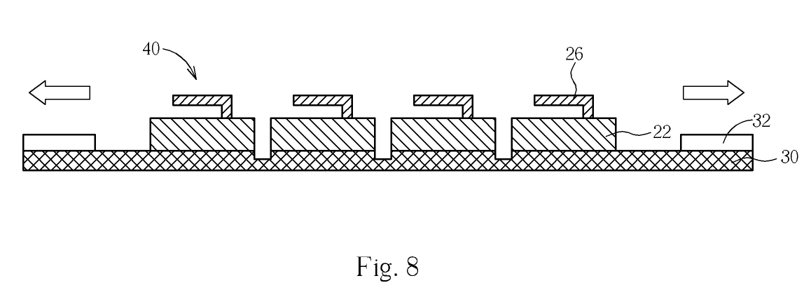

Please refer to FIG. 7. Since the method uses the first bonding layer 30 and the second bonding layer 38 to bond the dies 40 to the carrier wafer 36, each die 40 is maintained at the same distance between each other as the distance between the dies 40 between the wafer segment process. A wafer-level testing in which a probe card or other testing means is used is performed. The function and the yield of the devices 40 are tested more accurately when the testing is performed after the dies 40 are formed. In this preferred embodiment, the material of the second bonding layer 38 is thermal tape. The second bonding layer 38 may be removed from the carrier wafer 36 and a surface of the first bonding layer 30 by heat without damaging the first bonding layer 30. The method for removing the second bonding layer 38 depends on the material of the second bonding layer 38. It is worth noting that selection of the material of the second bonding layer 38 should take the material of the first bonding layer 30 into consideration. And thus, the first bonding layer 30 will not be damaged or lose its adhesive ability while removing the second bonding layer 30. Please refer to FIG. 8, the first bonding layer 30 is extended to release the dies 40, and a wafer expansion and sorting process is performed to pick up the known good dies 40 for the following packaging process.

In conclusion, the method of the present embodiment combines a wafer-level MEMS device testing process into the semiconductor fabrication processes. The characteristic of the present invention is that each die is maintained at the same distance between each other as the distance between the dies before the wafer segment process. In addition, the device may be tested twice: 1) after device formation and 2) after die formation. Consequently, performance of the present invention increases yield and decreases labor cost and time cost during manufacturing.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of wafer segmenting capable of maintaining a distance between dies, comprising:
providing a device wafer comprising a plurality of devices on a top surface;
forming a passivation layer on the top surface of the device wafer to cover the devices;
attaching a bottom surface of the device wafer to a first bonding layer;
providing a carrier wafer, and using a second bonding layer to adhere the first bonding layer to the carrier wafer;
performing a segment process to segment the passivation layer and the device wafer to form a plurality of dies, each die being maintained at the same distance between each other by means of the second bonding layer as the distance between the dies before the segment process;
removing the passivation layer to expose the devices, and performing a wafer-level testing; and
removing the second bonding layer and the carrier wafer.

2. The method of claim 1, wherein the first bonding layer comprises an extendable film.

3. The method of claim 2, further comprising extending the extendable film, and performing a wafer expansion and sorting process after removing the second bonding layer and the carrier.

4. The method of claim 2, wherein the first bonding layer comprises UV tape.

5. The method of claim 2, wherein the first bonding layer comprises blue tape.

6. The method of claim 1, wherein the second bonding layer comprises thermal tape.

7. The method of claim 1, wherein the passivation layer comprises photoresist.

8. The method of claim 1, wherein the segment process comprises a laser segment process.

9. The method of claim 1, wherein the segment process comprises an etching process.

10. The method of claim 1, wherein the devices comprise micro-electromechanical system (MEMS) devices.
